(19) United States
(12) Patent Application Publication
(10) Pub. No.: US 2024/0033994 A1
(43) Pub. Date: Feb. 1, 2024

(54) Material Mixing For Additive Manufacturing Apparatus

(71) Applicant: Board of Trustees of Michigan State University, East Lansing, MI (US)

(72) Inventors: Michael Thomas CRATON, Lansing, MI (US); Ioannis PAPAPOLYMEROU, Okemos, MI (US); Premjeet CHAHAL, Okemos, MI (US); John D. ALBRECHT, Okemos, MI (US)

(73) Assignee: Board of Trustees of Michigan State University, East Lansing, MI (US)

(21) Appl. No.: 18/378,218

(22) Filed: Oct. 10, 2023

Related U.S. Application Data
(62) Division of application No. 17/388,418, filed on Jul. 29, 2021.
(60) Provisional application No. 63/067,001, filed on Aug. 18, 2020.

(51) Int. Cl. B29C 64/314; B29C 64/112; B29C 64/393; B33Y 10/00; B33Y 30/00; B33Y 40/00; B33Y 70/10; B33Y 80/00; B33Y 50/02

(52) U.S. Cl. CPC B29C 64/314; B29C 64/112; B29C 64/393; B33Y 10/00; B33Y 30/00; B33Y 40/00; B33Y 70/10; B33Y 80/00; B33Y 50/02; B29L 2031/3425

(57) ABSTRACT

Material mixing for an additive manufacturing apparatus is provided. A further aspect employs multiple material inlets for simultaneously feeding a polymer and/or nanocomposite material in at least a first inlet, and ceramic or other particles in at least a second inlet, to a single additive manufacturing outlet nozzle. In another aspect, a three dimensional printing machine varies a chemical or compounding characteristic, such as a loading percentage, of printing material during printing. In another aspect, in situ mixing of a polymer and/or nanocomposite with variable amounts of ceramic, magnetic or other particles therein in an additive manufacturing apparatus, such as a multi-material aerosol jet printing machine.

### CROSS-REFERENCE TO RELATED APPLICATION

This application is a divisional of U.S. patent application Ser. No. 17/388,418, filed on Jul. 29, 2021, which claims the benefit of U.S. Provisional Application Ser. No. 63/067,001, filed on Aug. 18, 2020, both of which are incorporated by reference herein.

### GOVERNMENT RIGHTS

This invention was made with government support under DE-NA0002839 awarded by the U.S. Department of Energy. The government has certain rights in the invention.

### BACKGROUND AND SUMMARY

The present application generally pertains to additive manufacturing and more particularly to a material mixing system for an additive manufacturing apparatus.

Three dimensional printing of electronic interconnects are known. See, for example, PCT Patent Publication No. WO 2019/222410 A1 entitled “Manufactured Interconnect Packaging Structure” which published on Nov. 21, 2019 to common inventors Papapolymerou, Chahal, Albrecht and Craton, and is incorporated by reference herein. While this prior three dimensionally printed interconnect is a significant improvement in the industry, additional improvements are desired.

An experiment is also known which used aerosol jet printing of NiO and YSZ ink suspensions mixed together as they entered a deposition head to print an anode of a solid oxide fuel cell, upon which a cathode and silver leads were hand pasted. Such a system is disclosed in Sukeshini et al., “Aerosol Jet Printing of Functionally Graded SOFC Anode Interlayer and Microstructural Investigation” (2013). This article, however, noted that in its experiment, “the overall performance of all cells was not satisfactory, and requires further optimization of the anode interlayer by altering the ink characteristics. Issues relating to improper mixing before reaching the deposition head or de-mixing of the aerosolized suspension on its transit from the nozzle to the substrate requires closer examination.” Thus, this article demonstrates the difficulties with this experiment and the unfulfilled desire for improvements.

In accordance with the present invention, material mixing for an additive manufacturing apparatus is provided. A further aspect employs multiple material inlets for simultaneously feeding a polymer and/or nanocomposite material in at least a first inlet, and ceramic or other particles in at least a second inlet, to a single additive manufacturing outlet nozzle. In another aspect, a three dimensional printing machine varies a chemical or compounding characteristic, such as a loading percentage, of printing material during printing. In another aspect, dynamic mixing of a polymer ceramic composite is used in additive manufacturing, such as three dimensional printing. Still another aspect includes in situ mixing of a polymer and/or nanocomposite with variable amounts of ceramic, magnetic or other particles therein in an additive manufacturing apparatus, such as a multi-material aerosol jet printing machine. An additional aspect creates an electronic or optical component, such as a thin nanocomposite and film ring resonator, a microwave integrated circuit, a capacitor, periodic structures such as a stepped impedance filter, a dielectric waveguide, a dielectric lens, a monolithically created dielectric-loaded antenna, a magnetic integrated circuit, materials whose coefficient of thermal expansion is tunable, impedance transformers, and metamaterials, by additively layering multiple materials, mixed together within an additive manufacturing head.

The present apparatus and method are advantageous over conventional devices. For example, the present apparatus and manufacturing method allow for real-time dynamic varying of the material mixture in the apparatus itself during emission of the mixed material from the outlet nozzle. This creates differing characteristics of the additively manufactured component from one region to another, due to easily controlled variations in the mixture but without requiring different formulations or batches of printing inks, and without requiring the inefficient use of mask-like patterns conventionally used for etching. The present real-time variation control optionally provides seamless and mid-processing, switching or changing between inks which are otherwise not designed to be mixed such as with dielectrics and conductors in a circuit. Furthermore, the present apparatus and method advantageously create smooth mechanical and chemical transitions between different material mixtures within an additively manufactured component. The present apparatus and method are ideally suited for quickly and cost-effectively creating thin electronic components including a polymer matrix ceramic or magnetic nanocomposite, which especially allows for tuning of relative dielectric or magnetic permittivity therein. Additional advantageous and features of the present apparatus and method will become apparent from the following description and appended claims, taken in conjunction with the accompanying drawings.

### BRIEF DESCRIPTION OF THE DRAWINGS

FIG. 1 is a perspective view showing a first embodiment of the present additive manufacturing apparatus;

FIG. 2 is a diagrammatic, perspective view showing the first embodiment additive manufacturing apparatus;

FIG. 3 is a perspective view showing a nozzle head of the first embodiment additive manufacturing apparatus;

FIG. 4 is an exploded, perspective view showing the first embodiment additive manufacturing apparatus;

FIG. 5 is a cross-sectional view, taken along line 5-5 of FIG. 3, showing the nozzle head of the first embodiment additive manufacturing apparatus;

FIG. 6 is a diagrammatic, perspective view showing the first embodiment additive manufacturing apparatus;

FIG. 7 is a perspective view showing ring resonators and MIMs capacitors created by the first embodiment additive manufacturing apparatus;

FIGS. 8 and 9 are top elevation views showing the ring resonators and MIMs capacitors created by the first embodiment additive manufacturing apparatus;

FIG. 10 is an enlarged and fragmentary, top elevational view, showing a capacitor of FIG. 9, created by the first embodiment additive manufacturing apparatus;

FIG. 11 is a chart of different composite materials used in the first embodiment additive manufacturing apparatus;

FIGS. 12-14 are graphs showing parasitic effects MIMs capacitors created by the first embodiment additive manufacturing apparatus;

FIG. 15 is an exploded, perspective view showing a microwave integrated circuit created by the first embodiment additive manufacturing apparatus;

FIGS. 16 and 17 are top elevation views showing the microwave integrated circuit created by the first embodiment additive manufacturing apparatus;

FIG. 18 is a cross-sectional view, taken along line 18-18 from FIG. 17, showing the microwave integrated circuit created by the first embodiment additive manufacturing apparatus;

FIG. 19 is a cross-sectional view, taken along line 19-19 from FIG. 10, showing the capacitor created by the first embodiment additive manufacturing apparatus;

FIG. 20 is a graph showing resistivity versus percentage of particles used in exemplary nanocomposites employed with the first embodiment additive manufacturing apparatus;

FIG. 21 is a perspective view showing a transmission line created by the first embodiment additive manufacturing apparatus;

FIG. 22 is a perspective view showing inductors created by the first embodiment additive manufacturing apparatus;

FIG. 23 is a perspective view showing a second embodiment feeding conduit assembly of the present additive manufacturing apparatus;

FIG. 24 is a bottom elevation view showing the second embodiment feeding conduit assembly of the present additive manufacturing apparatus;

FIG. 25 is a perspective view showing a third embodiment feeding conduit assembly of the present additive manufacturing apparatus; and

FIG. 26 is a bottom elevation view showing the third embodiment feeding conduit assembly of the present additive manufacturing apparatus.

### DETAILED DESCRIPTION

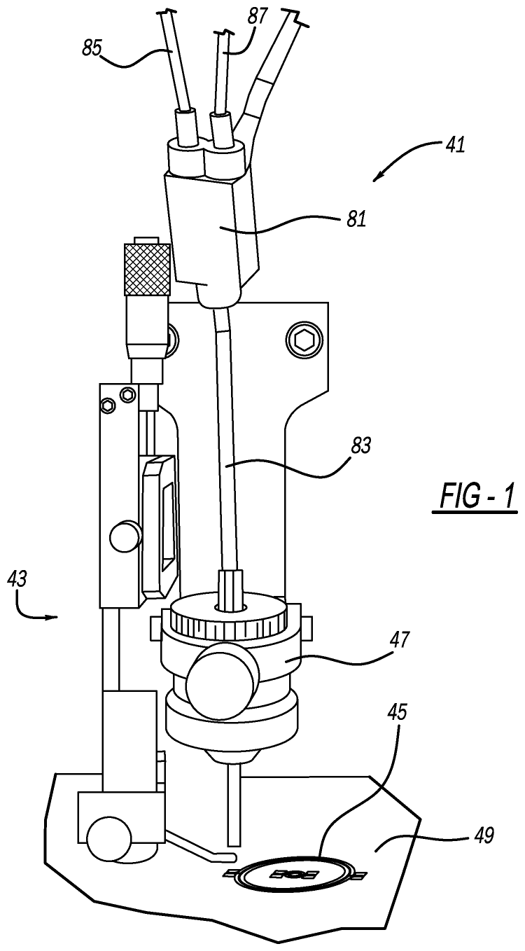

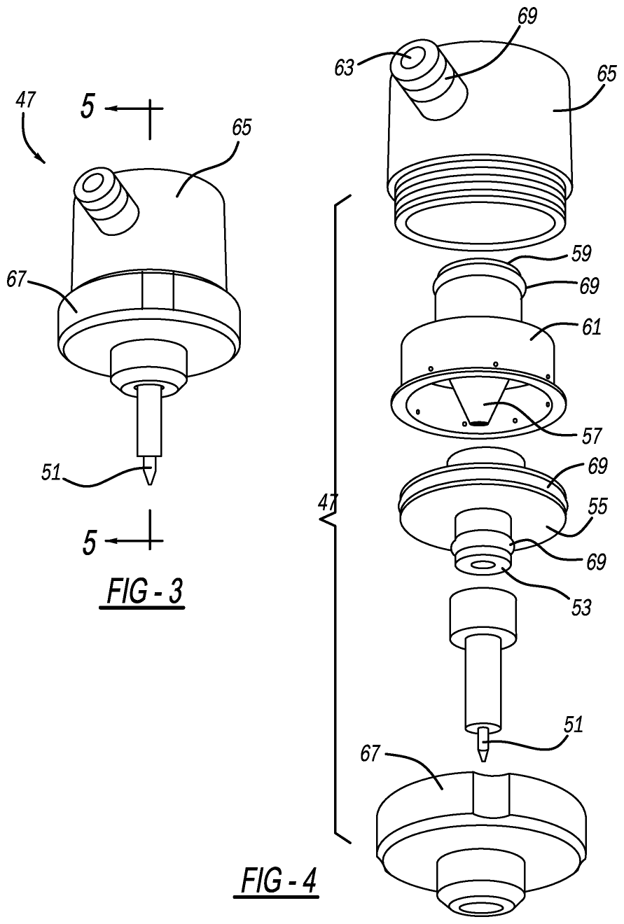

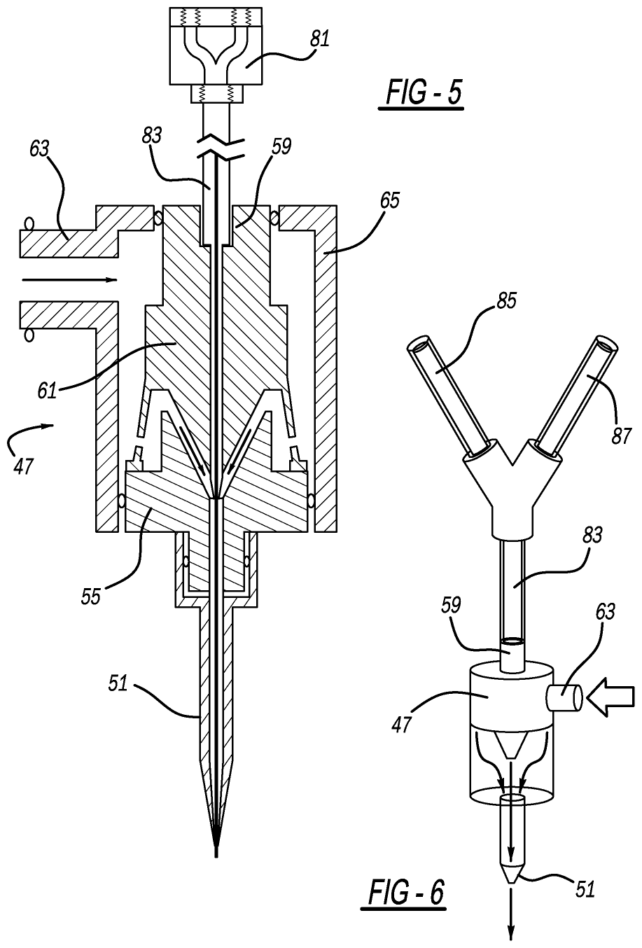

A first embodiment of an additive manufacturing apparatus 41 is illustrated in FIGS. 1-6. Apparatus 41 includes a multi-material aerosol jet printing (“MMAJP”) machine 43, aerosol materials, particles, and one or more electronic components. A first exemplary electronic component is a resonator ring workpiece 45 where the aerosol materials are polymers and the particles are nanoparticles. As will be discussed with other embodiments, the aerosol materials and particles may alternately be: two or more nanomaterials, two or more polymers, a polymer precursor plus a reagent, other layerable inks with separately fed filler particles; or other variations and combinations thereof.

MMAJP machine 43 includes a three-dimensional printing head 47 which is either: (a) vertically and horizontally movable in three axes by an electric motor-actuated, horizontally elongated gantry and interconnected vertically elongated frame, above a stationary stage or table 49; (b) head 47 is vertically movable and horizontally moving in one axis while table 49 is horizontally movable in a perpendicular axis; or (c) head 47 is stationary while table 49 is movable in three or five axes (including rotation) via one or more motorized or fluid powered actuators. Table 49 (and optionally a substrate carrier located thereon) is heated and supports ring resonator workpiece 45.

Head 47 includes an outlet nozzle 51, a focused aerosol outlet 53 of a lower insert 55, a cone 57 and an aerosol inlet 59 of an upper insert 61, and a sheath gas inlet 63 of an outer shell 65. An internally threaded retaining nut 67 is locate at the bottom of head 47 for retaining the other components within the outer shell. O-rings 69 seal between various of the head components.

A fitting 81 is connected to aerosol inlet 59 via a vertically elongated primary conduit 83 or alternately directly by threads of fitting 81 engaging threads of aerosol inlet 59. Fitting 81 of the first embodiment apparatus 41 is preferably of a Y-configuration which receives two feeding conduits 85 and 87. Conduits 85 and 87 are preferably flexible to allow movement of head 47, but may alternately be rigid. An exemplary fitting is a wye-shaped, push-to-connect tube fitting that can be obtained from McMaster-Carr Supply Co.

Apparatus 41 additionally includes atomizers 91 and 93, a liquid drip catcher 95 with an exhaust outlet 97, and aerosol heating coils 99 wound around feeding conduits 85 and 87. Atomizer 91 is shown as a pneumatic atomizer while atomizer 93 is shown as an ultrasonic atomizer; pneumatic nitrogen is introduced at port 101 and nitrogen carrier gas is introduced at port 103. However, the type of atomizer may vary depending on the materials employed therein; for example, two or more ultrasonic atomizers, or two or more pneumatic atomizers may be used. An aerosol stream of nitrogen with suspended liquid ink is fed to fitting 81 of head 47 by conduit 85, and an aerosol stream of nitrogen with suspended solid nanoparticles is fed to fitting 81 by conduit 87, as will be discussed in greater detail hereinafter. In various embodiments discussed herein, the aerosol stream of ink fed by conduit 85 may be conductive, ceramic, magnetic, polymeric or the like.

A programmable controller 111 is connected to and selectively controls valves 113 from open, closed and intermediate positions in order to dictate the quantity of material and particles flowing through feeding conduits 85 and 87. Controller 111 is also connected to the actuators moving head 47 and/or table 49. Thus, the software of controller 111 may be programmed to automatically vary the valve positions and therefore, a material versus particle mixture characteristic, such as loading percentage, to head 47 either before or during printing of the composite exiting nozzle 51. Controller 111 has input buttons or a touch screen, an output display screen, a microprocessor and memory for operating and storing software instructions. Various flow rate and temperature sensors may be positioned adjacent the head and conduits to monitor material, particle or equipment characteristics thereof, with the sensed output signals being sent to the controller in a closed loop and real-time manner, which may cause the controller to further automatically adjust and vary the mix ratio or other settings. This centralized software programmed controller 111 and valve 113 arrangement is well suited when more than two atomizers are used or when it is desired to prevent cross-contamination of multiple inks that are not intended to be mixed. A more simplistic configuration, however, does not require an automated controller to actuate valves and, instead, pre-set mass flow controllers or programmable valves are more simply used at positions 97, 101 and 103, by way of example.

More specifically, dynamic mixing of polymer material and ceramic particles create a composite material additively layered to create the electronic component by the present three-dimensional printing process. Using this in situ mixing strategy, polyimide and barium titanate (BaTiO₃) nanocomposite films are additively printed with variable levels of ceramic loading. By mixing composites in situ, the apparatus can dynamically alter the ceramic loading of the printed material without the need to formulate multiple inks and pattern 3-D structures, and also avoids the conventional use of photosensitive materials for mask etching. Furthermore, aerosol jet printing advantageously creates features, such as circuit traces, as small as 10 μm with 6-15 μm gaps (more preferably 15 μm gaps), while also printing on conformal surfaces and printing around objects with large variations in size.

Use of BaTiO₃ with the present MMAJP apparatus is of specific interest for electronic packaging because of its high relative dielectric constant (εᵣ), between 500 and 7000. εᵣ of BaTiO₃ can change as a function of crystal orientation, preparation, and the temperature it is measured at, BaTiO₃ is useful for components like capacitors that benefit from a high zᵣ. Other nanocomposites, such as barium strontium titanate; (BST), is alternately employed since it has desirable electrically tunable dielectric properties which are ideally suited for use with the present MMAJP apparatus, Alternate nanomaterials with magnetic properties such as iron, nickel, cobalt, or MnFe₂O₄ are also well suited for use with the present MMAJP apparatus. Similarly, the present MMAJP apparatus uses polyimide (PI) as the base aerosol polymeric material since it is particularly well suited for creating microwave and millimeter-wave electronics, due to its low-loss characteristics and high-temperature capabilities. Alternate aerosol polymeric materials can be employed with the present apparatus such as polyvinylidene fluoride (PVDF), thermoplastics, and epoxy.

The present apparatus and method additively manufacture electronic components or workpieces using nanocomposites where the mixing ratio of the composite can be adjusted in situ during the manufacturing process for on-demand composites while simultaneously providing for patterned structures. This advantageously allows for the fabrication of smooth gradients and abrupt changes in materials without requiring physical hardware changes. The present exemplary microwave filters or periodic structures benefit from the ability to either change a material property abruptly or gradually, which allows for tuning of mechanical properties, a coefficient of thermal expansion (“CTE”), tuning relative dielectric permittivity, and/or tuning relative magnetic permeability.

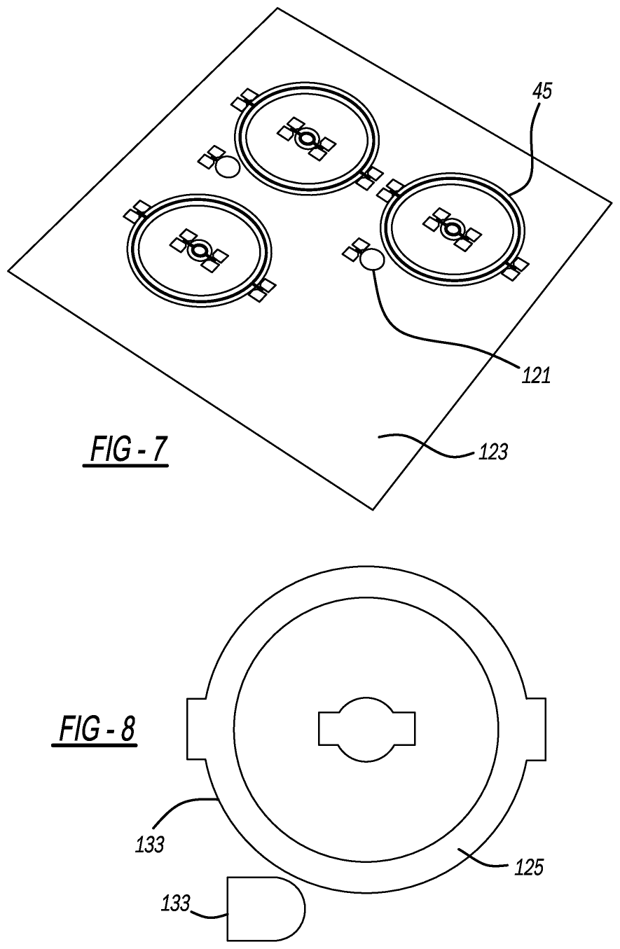

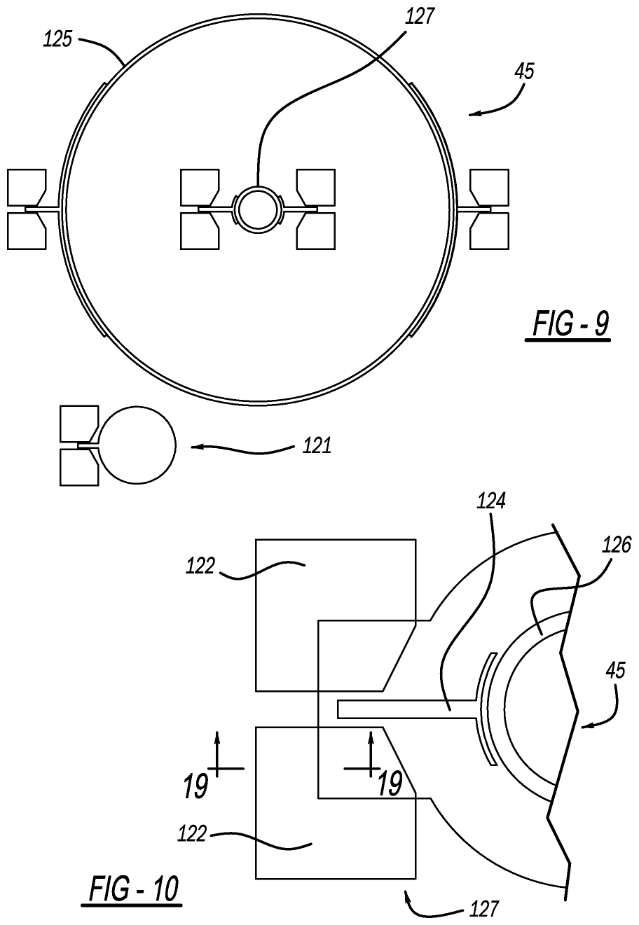

The present MMAJP apparatus and method were used to additively print nanocomposites to create ring resonators 45 and parallel-plate metal-insulator-metal (“MIM”) capacitors 121 on a molybdenum copper alloy (MoCu) of 85% Mo and 15% Cu (American Elements), film substrate 123. This can best be observed in FIGS. 7-10 and 18-22. Connection pads 122, coaxial feed lines 124, and rings 126 are additively printed, with gaps located therebetween. An adhesion promoter may optionally coat an upper working surface of substrate 123 before layers are printed thereon; one such promoter is VM652 which may be obtained from HD MicroSystems. Alternately, substrate 123 can be ceramics, such as alumina or LTCC) or flexible, such as PI films or LOP, by way of non-limiting examples.

A first larger diameter, ring resonator circuit 125 is additively layered as a film from the nanocomposite material and is designed for an initial resonance less than 12 GHz. Furthermore, a second smaller diameter, ring resonator circuit 127 is additively layered as a film from the nanocomposite material, located concentrically within the first circuit 125, and is designed for an nitial resonance less than 110 GHz. These closed loop MS ring resonator circuits have microwave or millimeter-wave properties, and are designed to operate in a 50-Ω environment. Substrate 123 is of a dielectric nature and approximately 20 μm thick, with an exemplary dielectric εᵣ=3.5, a wavelength at 110 GHz is λ=1.468 mm, or with a dielectric εᵣ=10, and a wavelength at 110 GHz is λ=0.862 mm. A small gap may be desired between the printed circuit traces of each resonator.

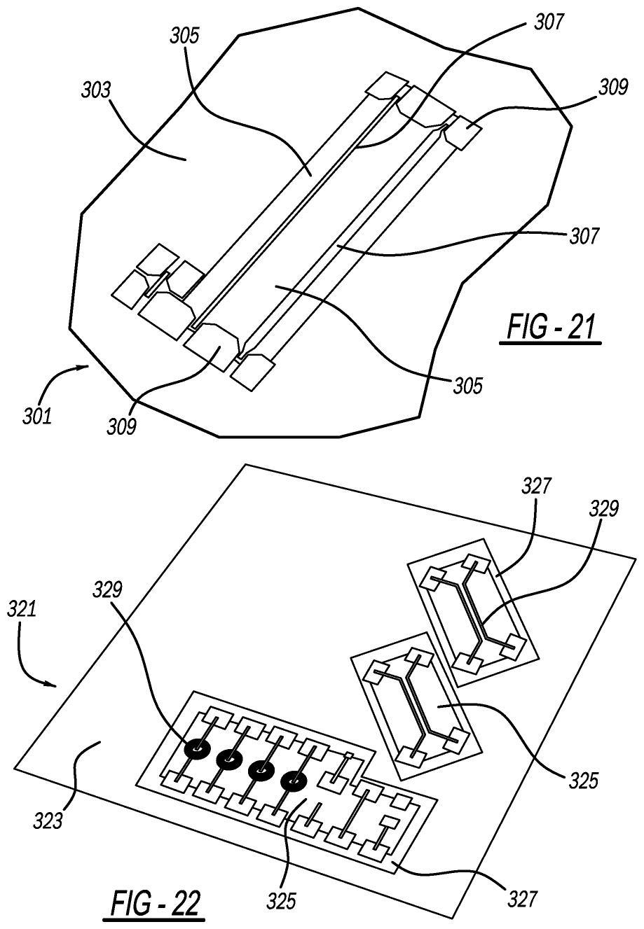

An electrically conductive silver ink 131 (see FIGS. 21 and 22) is additively printed from the same or different MMAJP nozzle to create the circuit traces, with each circuit line preferably having a width of about 10 μm and a gap therebetween of about 20 μm. Each silver ink circuit trace 131 preferably is made of 2-20 additively printed layers with a thickness of 1-40 μm total, and more preferably of a total thickness of about 5 μm. Silver ink circuit traces are layered on top of deposited PI material layers 134 (without BaTiO₃ particles therein), nanocomposite layers 133, directly upon substrate 123 and/or a die or integrated circuit chip 137.

PI material layers 134 have areas 135 additively printed directly upon substrate 123 and other areas 136 printed directly onto or contacting against a die or integrated circuit chip 137. The substrate is approximately 5 mm thick film in one example. The nozzle-emitted PI layers 134 preferably consist of 2-200 layers with a total thickness T of 1-200 μm, more preferably about 5-50 μm, and even more preferably about 25 μm at its larger and flat areas 135 where an outer surface thereof is elongated parallel to an outer face of substrate 123 upon which nanocomposite material 133 is located. Mixed and nozzle-emitted nanocomposite material 133 preferably consists of 2-200 layers with a total thickness of 1-200 μm, more preferably about 1-5 μm, and even more preferably about 2 μm at its larger and flat areas where an outer surface thereof is elongated parallel to an outer face of substrate 123 upon which nanocomposite material 133 is located.

PI polymeric material and BaTiO₃ particles are employed in a preferred embodiment of the mixed nanocomposite 133 emitted from the outlet nozzle of the MMAJP head. In one example, a first aerosol ink uses 99.9% cubic 50 nm BaTiO₃ nanoparticles (such as can be obtained from US Research Nanornaterials, Inc.) in combination with a BYK-W910 dispersant. A second ink contains a PI material precursor made with a 15% wt. polyamic acid catalyst solution in NMP (such as can be obtained from Sigma Aldrich). Both the BaTiO₃ and PI inks used N-methyl-pyrrolidone (NMP) (such as can be obtained from Sigma Aldrich) as a solvent.

In one example of the BaTiO₃ ink, a solution consists of NMP and 2% wt. BYK-W910, to which is mixed 3.5% wt. and 7% wt. BaTiO₃ in NMP. Ultrasonication is used to mix this solution for 1 hour, which yields an ink of 0.07% wt. dispersant and 7% wt. BaTiO₃ in NMP. In one example of the PI ink, a 15% wt. polyamic acid solution is added to NMP, which is further diluted in 5% wt. polyamic acid to lower the viscosity of the ink in order to improve atomization.

One suitable, exemplary silver ink used to fabricate the conductive features and circuits, can be obtained from Clariant AG as Prelect® TPS 50 brand nanoparticle ink. The silver ink is composed of 25% wt. silver ink material in deionized water, which is similarly diluted to improve atomization. This ink was mixed under ultrasonication for 1 hour. The silver ink is preferably emitted from the same nozzle and head as with the PI and composite materials, or alternately, from a separate head and differently sized nozzle of the present three-dimensional printing machine.

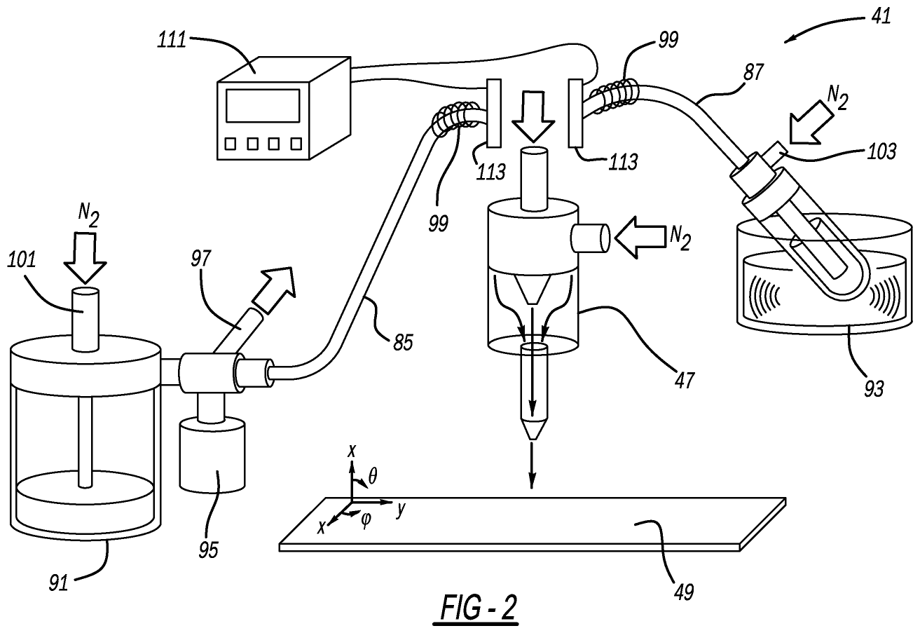

The in-head mixing will again be discussed with reference to FIGS. 2, 5 and 6. The present process mixes the materials in an aerosol form rather than in liquid form, precluding the necessity to formulate new liquid mixtures for every concentration. By mixing aerosols, composites can be mixed in printing head 47 as they are being deposited onto the upper surface of table 49. The mixed composite material is contained in a focused aerosol stream which allows printing at a standoff height up to 10 mm while maintaining minimum printed feature sizes less than 10 μm.

Feeding tubes or conduits 85 and 87 each have an internal diameter of approximately 1.5 mm, and it is desired to maintain a laminar aerosol flow free of clogs with minimal overspray after printing. Therefore, turbulent mixing should be avoided since such is prone to clogging the conduits. Instead, the present apparatus and process use advective mixing. The two (or more) aerosols fed into fitting 81 are not well-mixed at that point. The combined aerosols are thereafter focused with a sheath gas of N₂ in print head 47. Thus, the aerosol materials and particles rapidly mix through advection in head 47 when the flow is confined during focusing.

The ambient temperature during printing ranged from 20° C. to 23° C. The PI ink is maintained at about 25° C. during printing and the BaTiO₃ ink is maintained at about 27.5° C. The higher temperature for the BaTiO₃ ink lowers the ink viscosity to improve the atomization rate. Furthermore, table 49 is heated to about 100° C. which beneficially allows the polyamic acid to dry as it is deposited, thereby creating a smoother surface of the printed workpiece. The sheath (focusing) gas flow rate should be set to promote laminar flow and avoid turbulent flow. Prior to printing the conductive silver layers, the dielectric is heat cured to imidize the polyamic acid. The printed silver ink traces are similarly heat cured to make the ink conductive.

Optionally controller 111 changes one or more settings of valves 113 and/or of pumps, to gradually change a mix characteristic of the composite material exiting head 47. For example, the mixture ratio or loading quantity of BaTiO₃ relative to PI may increase from one side of the manufactured layer or component to the other the other side, thus, an increase in εᵣ from one area to another. This real-time in-process variation is ideally suited for additively creating the ring resonators and MIM capacitors. Alternately, controller 111 can be programmed to automatically cause a mixture variation in the middle, peripheral edges, repeating and spaced apart patterns, or other localized areas of a layer and/or workpiece component.

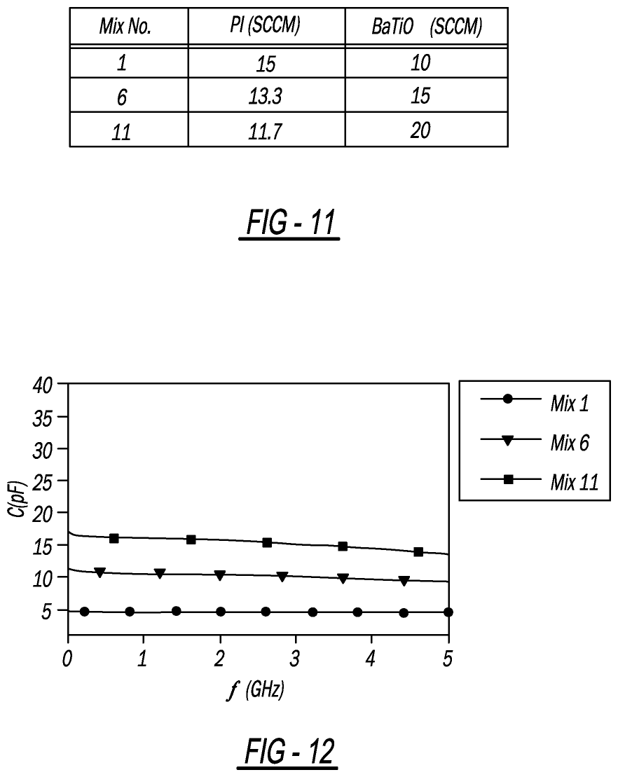

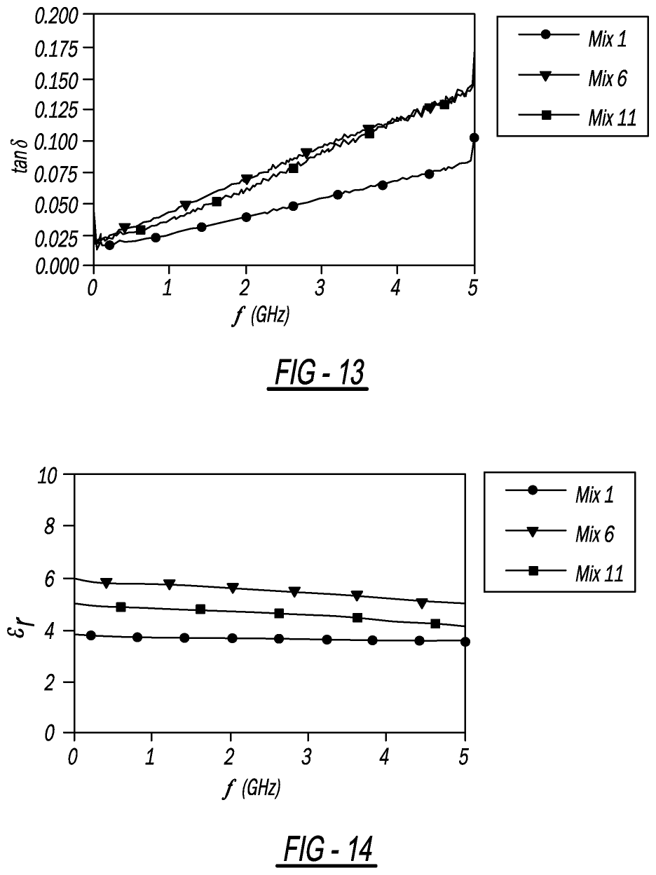

The table of FIG. 11 and graphs of FIGS. 12-14 show calculations from measured MIM capacitors utilizing three different mixture examples. FIG. 12 shows capacitance, FIG. 13 shows tan δ and FIG. 14 shows εᵣ at different frequencies. The capacitor εᵣ and tan δ calculation errors increase with frequency due to the resonance of the capacitor and increasing error from parasitic effects not taken into account. This behavior is most apparent in the tan δ calculation. The loss tangent of the three composites is calculated to be 0.020, 0.030, and 0.028 for mixes 1, 6, and 11, respectively, at 0.5 GHz. The expected capacitances yielded values ranging from 3.4 to 8.9. Moreover, these capacitors are between 2 and 4 μm thick.

In one example of the capacitor and ring resonator, an increasing amount of BaTiO₃ nanoparticles is present in the films. Using the lowest common denominator of atomic content of elements present in BaTiO₃, an estimate of the % vol, of BaTiO₃ in the composite using for the density of BaTiO₃, ρ=6.02 g/cm³, and for PI, 1.42 g/cm³ can be calculated. For mix 11, there is about 58.25 wt. % BaTiO₃, which corresponds to 24.8 vol. %, For mix 6, there is about 15.41 wt. % BaTiO₃ corresponding to 4.12 vol, %.

Another example of a suitable printable composite uses a polyamic acid PI precursor ink made by HD Microsystems PI2611, which has a published εᵣ of 2.9 and a loss tangent of 0.002. This layered exemplary new dielectric film for a component created in this example, is cured at 350° C. to ensure 100% imidization. The sample is thereafter held under vacuum for a minimum of 12 hours prior to curing, in order to ensure that no moisture absorption takes place, and also to mitigate air bubbles incorporated into the films during the MP process. For these parts, twice as many silver layers are printed and a coupling angle of the annular coupling structure of the resonator is reduced from 80° to 60°. This allows the measurement of two more resonances from 0 to 67 GHz before the coupling structure begins to radiate at a quarter wavelength.

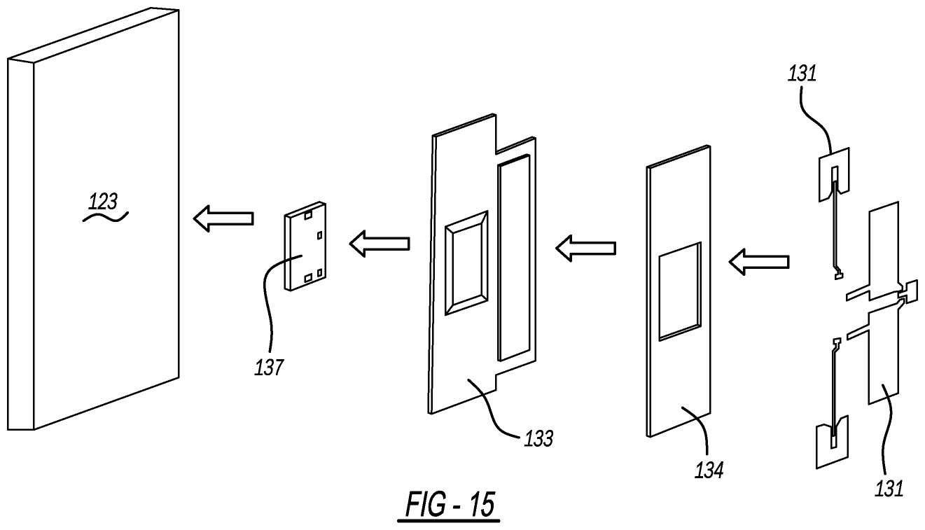

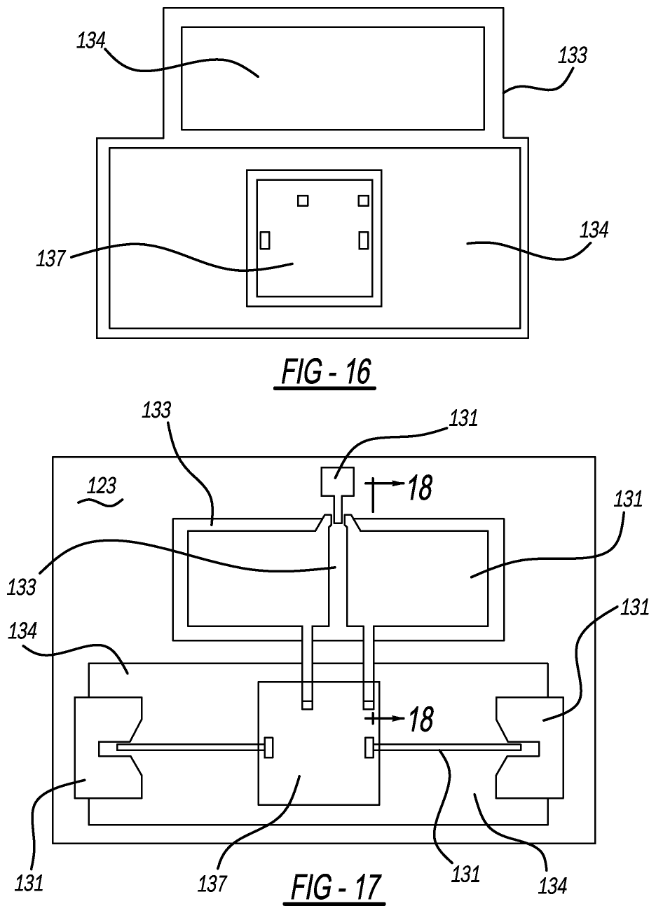

Another exemplary electronic component or workpiece created by the present MMAJP apparatus and method will now be discussed, more specifically for additively manufacturing microwave packages with integrated active and passive components. Referring to FIGS. 15-19, component packages are constructed using a chip-first approach where dielectric substrates 123 and conductive interconnects 131 are built up in an additively layered manner around a power amplifier bare die 137, attached to carriers. Bypass capacitor dielectrics are printed using multi-material aerosol jet printing, where aerosols of barium titanate and polyimide inks are mixed within the printing machine head to fabricate a high dielectric constant polymer matrix nanocomposite film. The present example integrates a complete system-in-package, including required bypass capacitors and active components. In our chip-first approach, the individual die is initially placed and the remaining package is additively layered and built up around the amplifier MMICs. As with the previous example, this one also is created using the present MMAJP polymer-matrix nanocomposite and dielectric thin films composed of polyimide and barium titanate.

It is expected that the present exemplary component beneficially obtains a package loss <2.3 dB across an entire 5-20 GHz passband with an average passband loss <1.3 dB. Furthermore, the present exemplary component achieves a maximum packaged gain of 21.7 dB compared with a nominal gain of 22 dB for the bare die. And large-signal measurements of a maximum Pₒᵤₜ=21.9 dBm are expected as compared with the manufacturer specified Pₛₐₜ˜22 dBm.

Besides demonstrating an improved package performance, the present apparatus integrates AM bypass capacitors. The integrated capacitors are hereby fabricated using MMAJP, which are patterned without the use of any photosensitive materials or etching. The present exemplary packaged circuits should advantageously have improvements in gain, output power and bandwidth relative to a conventional QFN chip-scale lead frame package requiring external capacitors.

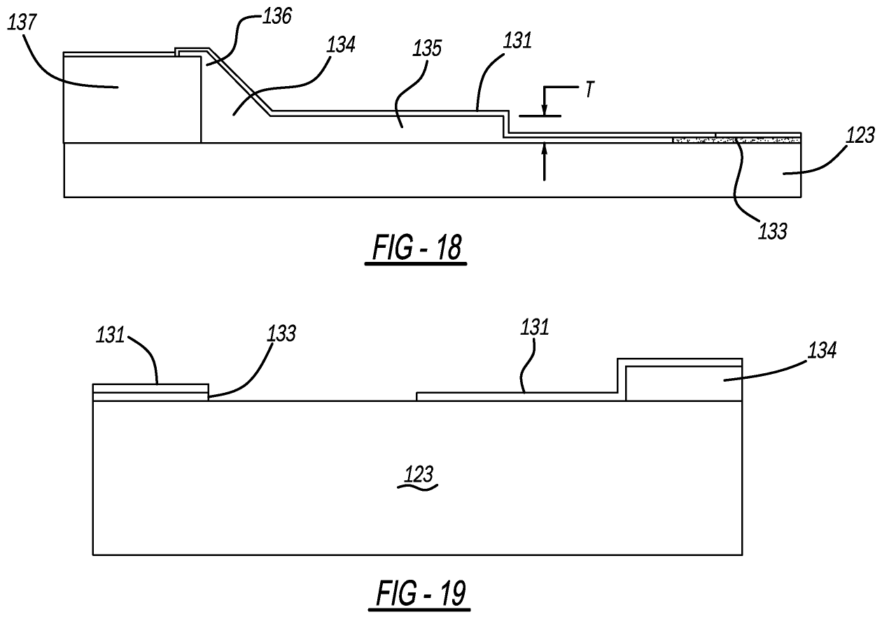

Substrate 123 of the present exemplary component is a molybdenum copper alloy matching a coefficient of thermal expansion (“CTE”) of GaAs die 137. Additively layered, printed silver microstrip (“MS”) transmission lines or traces 131 form die interconnects as well as a conductor backed coplanar waveguide (“CPW”)-to-MS transition. There are also additional grounding straps to the MoCu carrier. Printed Ag traces 131 serve as a top metal layer of the MIM capacitors. Furthermore, the MoCu carrier acts as a ground reference for the CPW, MS, and the die as well as a bottom metal layer for the MIM capacitors. The surfaces of dielectric layers 134 are multileveled and not coplanar, which would be impractical to fabricate by conventional lithography and etching processes. Dielectric layers 134 include a thin film composing the capacitor dielectric, a thin layer that borders the capacitors, a thick layer on which the MS lines are printed, and printed dielectric ramps, or fillets, up to a top surface height of die 137 as can best be observed in FIG. 18. The die is passivated as received, but a modified version could optionally include a final printed passivation layer of PI or some other material if required.

Fabrication of the present exemplary component will hereinafter be discussed. A 0.5-mm-thick 85% Mo 15% Cu plate is first mechanically polished and then the die is attached thereto using an Epo-Tek H20E Ag epoxy. The epoxy is cured in a nitrogen environment to prevent oxidation of the MoCu. Subsequently, an exemplary VM651 adhesion promoter is applied immediately prior to printing, to improve the late adhesion of the PI and nanocomposites.

The PI ink of this embodiment includes PI2611 polyamic acid diluted to 33 vol. % PI2611+N-Methyl-2Pyrrolidone. The polyamic acid is diluted in order to improve atomization during printing. Cured PI2611 has a published r=2.9 and tan δ=0.002 at 1 kHz. PI2611 is chosen for its low CTE to match to the die and the MoCu carrier, such that the published CTE of cured PI2611 is 3 ppm/° C. Alternate mixtures and dilutions of inks may be used.

BaTiO₃ ink of the present example is 20 wt. % 50-nm cubic phase BaTiO₃ dispersed in NMP. The nanocomposite is mixed in the MMAJP printing head as previously explained hereinabove. Finally, the present Ag ink is 25 wt. % Clariant Prelect TPS 50 plus deionized water. Similar to the polyamic acid solution, the Ag is diluted to improve atomization during the aerosol-generating process. All inks are ultrasonically mixed for at least 1 hour prior to printing.

All printing is performed with the MoCu carrier grounded in order to prevent any accidental static charge build up during the aerosol deposition process. The ambient temperature during printing varied between 22° C. and 24° C. Printing is performed with an exemplary Optomec Aerosol Jet 5× printer at a print speed of about 1 mm/s and the PI ink is placed in an aerosol form with a pneumatic atomizer in this exemplary embodiment. The sheath gas prevents the aerosols from contacting the print nozzles and allows for finer definition in printing. PI ink is maintained at a temperature of about 25° C. during printing and is heated above the ambient temperature so that it does not vary with the ambient temperature of the room.

The liquid BaTiO₃ ink is maintained at a temperature of about 27.5° C., and heated to reduce its viscosity and therefore improve atomization. The print surface for all dielectrics is heated to approximately 100° C. which allows the ink to dry as it is printed, thereby improving the surface quality and allowing for thicker films to be deposited. For all dielectric inks of this example, a 300 μm diameter nozzle is used.

The first layers of PI and the in-head mixed nanocomposite materials are deposited by the nozzle after the adhesion promoter was applied to the MoCu carrier. In this nonlimiting example, four layers of PI ink are deposited, with a 5 μm design target thickness in the thinnest area with an upper surface thereof generally parallel to an upper surface of substrate 123. Two layers of the BaTiO₃ 133 are next deposited on substrate 123. Following this, PI fillets 136 are created by printing on an angle of about to normal along the edges of die 137, which is about 0.1 mm thick. This filet protects the sides of the die and allows a smooth transition from the PI to the die.

A soft bake of these initial layers is performed at a temperature of approximately 200° C. for a 2-min hold time, with a 2° C./min maximum temperature gradient in a nitrogen environment and a rise time of approximately 90 min. Following these initial layers, 20 layers of PI 135 are printed of about 30 μm design target thickness T followed by another soft bake. Finally, ten layers of PI are printed followed by a hard bake to achieve 100% imidization by heating the package to about 295° C. for a 1 hour hold time with a 2° C./min temperature gradient and a rise time of approximately 138 min, also in a nitrogen environment. Prior to each curing step, the packages are in a vacuum for several hours to prevent the films from absorbing moisture and to mitigate air bubbles that can otherwise become trapped in the films during printing.

Finally, Ag ink 131 is printed to form electrical connections to die 137. Ag ink is printed using a 150 μm diameter nozzle with an ultrasonic atomizer. In this nonlimiting example, three layers of Ag ink are printed and an additional three layers on the PI fillets at an angle of about 15° to normal. The Ag ink is cured in air at 180° C. with a 2° C./min temperature gradient and a rise time of approximately 80 min, for a 4 hour hold time; this curing profile is expected to achieve a conductivity of 39% of bulk Ag.

Other optional metallic particles in the composite are one or more of the following: barium strontium titanate (BST) (for electrical tuning), Cu+Mo (for low CTE metal), Ag (or another metal)+diamond (for low CTE/high thermal conductivity), Ag+carbon nanotubes (for increased structural strength of films or for sensor applications), Ag+graphene (for resistive material), Ag (or another metal)+nichrome (for thin film resistor material), or Au ink. Alternate polymers in the composite include one or more of the following: low εᵣ material like polyimide, high εᵣ material like polyvinylidene fluouride (PVDF), polyvinylpyrrolidone (PVP), epoxy (e.g. SU-8), or benzocyclobutene (BCB).

FIG. 21 shows another exemplary electronic component 301 created by the present apparatus and method. Here, magnetic transmission lines 307 are used for tuning relative magnetic permeability, μᵣ by ferromagnetic resonance on a ferrite composite substrate film 303. Polymeric and dielectric layers 305 are additively printed on substrate 303 upon which are printed silver conductive lines or traces 307 and connector pads 409. The substrate is about 40-60 wt. % of nickel zinc ferrite (Ni_{0.5}Zn_{0.5}Fe₂O₄) mixed with a polyimide polymer within the head.

FIG. 22 illustrates another magnetic nanocomposite component 321 which are inductors. They have a ferrite composite substrate film 323 which increases inductance density. Approximately 21 wt. % Ni_{0.5}Zn_{0.5}Fe₂O₄ is employed for the dielectric layers 327, PI is used for layers 325, and silver ink circuit traces 329 are printed thereon. The ferrite composite material acts as an absorber to reduce crosstalk in the circuits. Alternate magnetic materials includes cobalt ferrite. Alternate polymers may also be used with any of these magnetic compositions and additively manufactured component workpieces.

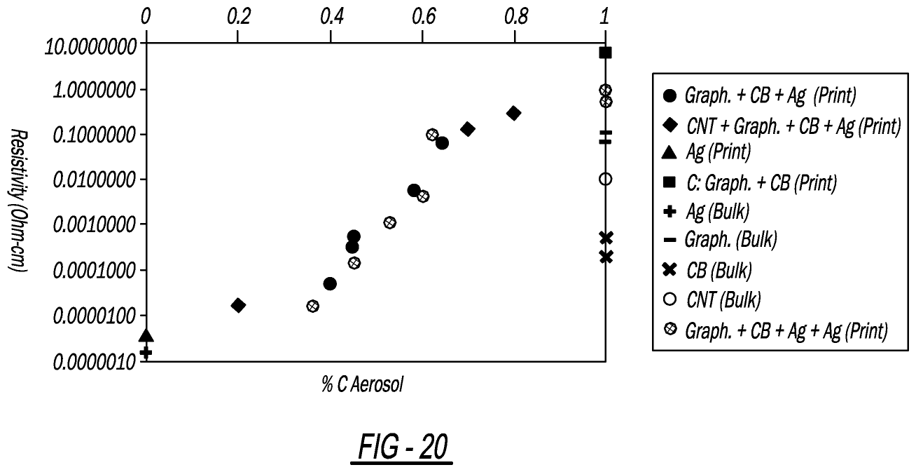

The graph of FIG. 20 illustrates expected tuning resistivity, p/conductivity and a for various exemplary silver and graphene metallic particles mixed with a polymeric matrix material to create composites within the printing head. The present apparatus and method are ideally suited for using these particles in the head-mixed composite to create resistors, attenuators, biasing networks and microwave loads.

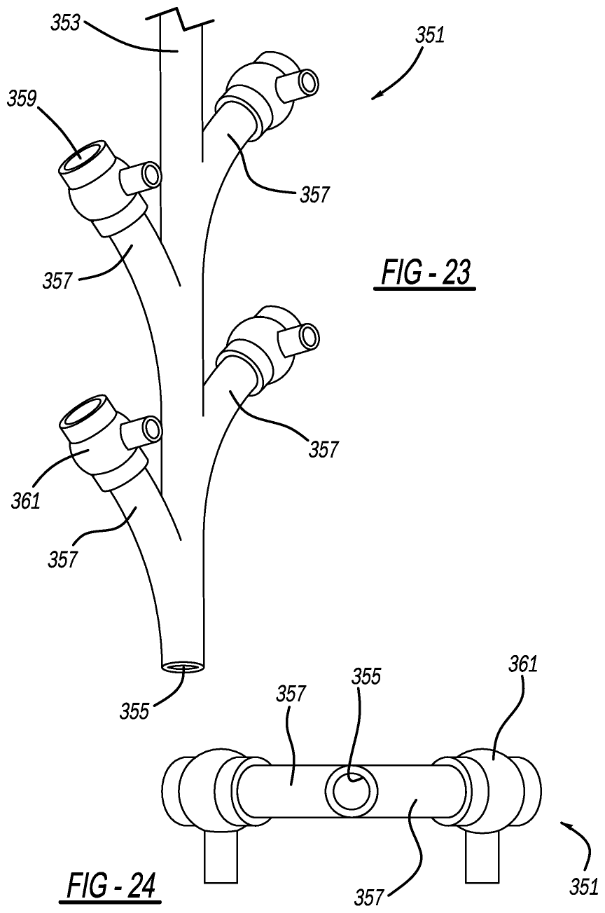

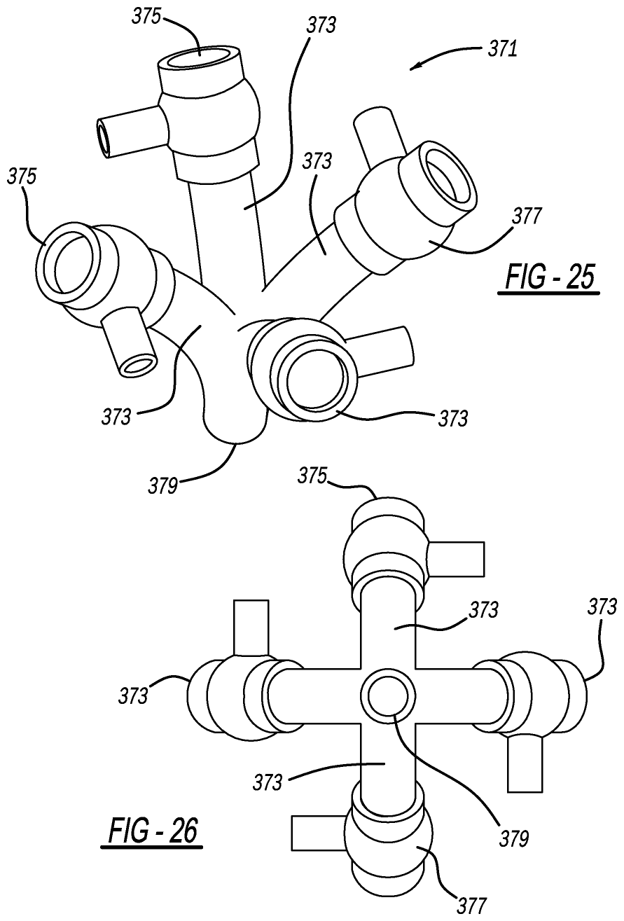

Finally, reference should be made to FIGS. 23-26 for alternate feeding and mixing conduits employed with the printing head. FIGS. 23 and 24 show a co-planar arrangement 351 of four (or more) feeding conduit branches 357, each having an inlet 359 and automatically adjustable valve 361. Branches 357 all have centerline axes co-planar with a primary elongated conduit 353 and an outlet 355 which is coupled to the printing head. FIGS. 25 and 26 illustrate another configuration 371 where at least four feeding conduit branches 373 are offset angled away from each other and from a centerline axis of an outlet 379. Inlets 375 and valves 377 are also associated therewith. This pattern creates a different mixing action than do the previously disclosed versions. Both multi-branch feeders allow for at least two different polymeric materials and at least two different types of particles to be mixed together. For example, a single MoCu substrate material may initially flow from a first branch to head and be emitted from the nozzle which is subsequently stopped, and then a pure PI polymer may flow from a second branch to head and be emitted from the nozzle, and after a period of time, BaTiO₃ particles flow from a third branch to head where it mixes with the still flowing PI material so both are emitted as a composite from the nozzle, and then the composite flow ceases after which Ag ink flows from a fourth branch to head for emission from the nozzle. Moreover, the valves can be automatically regulated by the programmable controller to vary the percentage of one or more of the materials greater than 0 and less than 100% during the printing operation.

Thin film lenses or spatial filters made from layered media are alternate examples of workpiece components ideally suited for creation by the present apparatus and method. The present apparatus and method is usable to create a Luneburg lens or any other lens that requires a gradient of zᵣ, in an additively layered and monolithic manner from the mixed composite material; the thin film lens can be fabricated by itself or embedded in another material using the present MMAJP apparatus. Many dielectric-loaded antennas would also benefit from the use of a process such as this. Moreover, the present MMAJP apparatus can be used to make workpiece components having periodic structures with the mixed composite material.

While various feature of the present invention have been disclosed, it should be appreciated that other variations may be employed. For example, different printing head configurations and positions can be employed, although various advantages of the present system may not be realized. As another example, the electrical components and workpieces may have a different shape and circuits than those illustrated, but certain benefits may not be obtained. Additionally, alternate materials may be used although some advantages may not be achieved. Alternately, variations in dimensions and layer quantity can be used, but performance may suffer. Moreover, while the presently illustrated MMAJP apparatus is preferred, other types of three dimensional printers or other additive manufacturing machines may be employed, although the present benefits may not be realized. Features of each of the embodiments may be interchanged and replaced with similar features of other embodiments, and all of the claims may be multiply dependent on each other in any combination. Variations are not to be regarded as a departure from the present disclosure, and all such modifications are intended to be included within the scope and spirit of the present invention.

The invention claimed is:

1. A method of additively manufacturing comprising:
(a) sending an aerosol material through a first conduit to a three-dimensional printing head;
(b) sending conductive or magnetic particles through a second conduit to the printing head;
(c) mixing the aerosol material and the particles within the printing head to create a composite material;
(d) emitting layers of the composite material from an outlet nozzle of the printing head to create a conductive ink circuit of an electronic component; and
(e) automatically controlling at least one valve with software instructions, stored in non-transient memory, to cause a mixing characteristic of the composite material to be varied while the aerosol material and the particles are flowing into the printing head and during printing of the composite material exiting the outlet nozzle.

2. The method of claim 1, wherein the mixing characteristic is a percentage of the particles in the composite material which is changed by more than 10% from one area of the electronic component to another area of the electronic component

3. The method of claim 1, further comprising sending a signal from at least one sensor, positioned adjacent to the printing head, to the software instructions which changes the mixing characteristic in response to the sensor signal in real-time, and the sensor signal sensing a flow rate.

4. The method of claim 1, wherein:
the particles include BaTiO₃ nanoparticles; and
the aerosol material includes polyimide.

5. The method of claim 1, wherein:
the particles are at least one of: BaTiO₃, barium strontium titanate, nickel ferrite, or cobalt ferrite; and
the aerosol material is at least one of: polyimide, polyvinylidene fluouride, polyvinylpyrrolidone, epoxy or benzocyclobutene.

6. The method of claim 1, wherein the mixing characteristic is automatically changed by the software instructions to provide mid-processing switching or changing between printing inks configured to create smooth mechanical and chemical transition between different material mixtures to create the electronic component including dielectric layers therein, without different ink formulations and without a patterning mask.

7. The method of claim 1, further comprising using the layers of the composite material to create a nanocomposite film being at least one of: a ring resonator, a microwave integrated circuit, or a capacitor.

8. The method of claim 1, further comprising:
using the layers of the composite material to create a nanocomposite film being at least one of: a magnetic integrated circuit or a transmission line; and
the particles being magnetic.

9. A method of additively manufacturing comprising:
(a) sending an aerosol material through a first conduit to a three-dimensional printing head;
(b) sending particles through a second conduit to the printing head;
(c) mixing the aerosol material and the particles within the printing head to create a composite material;
(d) emitting layers of the composite material from an outlet nozzle of the printing head to create an electronic component;
(e) the particles being at least one of: BaTiO₃, barium strontium titanate, nickel ferrite, or cobalt ferrite; and
(f) the aerosol material being at least one of: polyimide, polyvinylidene fluouride, polyvinylpyrrolidone, epoxy or benzocyclobutene.

10. The method of claim 9, further comprising automatically controlling at least one valve to cause a mixing characteristic of the composite material to be varied while the aerosol material and the particles are flowing into the printing head and during the composite material exiting the outlet nozzle.

11. The method of claim 10, wherein the mixing characteristic is a percentage of the particles in the composite material which is changed by more than 10% from one area of the electronic component to another area of the electronic component

12. The method of claim 9, further comprising automatically changing a mixing characteristic of the particles and the aerosol material in response to a real-time sensor signal.

13. The method of claim 9, wherein the particles include BaTiO₃ nanoparticles.

14. The method of claim 9, wherein the particles include barium strontium titanate.

15. The method of claim 9, wherein the particles include nickel ferrite.

16. The method of claim 9, wherein the particles include cobalt ferrite.

17. The method of claim 9, wherein the aerosol material includes polyimide.

18. The method of claim 9, further comprising using the layers of the composite material to create a nanocomposite film being at least one of: a ring resonator, a microwave integrated circuit, or a capacitor.

19. The method of claim 9, further comprising:
using the layers of the composite material to create a nanocomposite film being at least one of: a magnetic integrated circuit or a transmission line; and
the particles being magnetic.

20. The method of claim 9, further comprising automatically changing a mixing characteristic between printing inks to create dielectric layers of the electronic component, without different ink formulations and without a patterning mask.

21. A method of additively manufacturing comprising:
(a) sending an aerosol material to an additive layering head;
(b) sending ceramic, conductive or magnetic particles to the additive layering head;
(c) mixing the aerosol material and the particles within the additive layering head to create a composite material; and
(d) emitting layers of a composite material from the additive layering head.

22. The method of claim 21, further comprising:
varying a percentage of the particles relative to the aerosol material within the additive layering head simultaneously while emitting the layers of the composite material from the additive layering head; and
creating an electronic circuit with the composite material, at least a portion of the composite material being electrically conductive.

23. The method of claim 21, wherein the particles are at least one of: BaTiO₃, barium strontium titanate, nickel ferrite, or cobalt ferrite.

24. The method of claim 21, further comprising using the layers of the composite material to create a nanocomposite film being at least one of: a ring resonator, a microwave integrated circuit, or a capacitor.

25. The method of claim 21, further comprising:
using the layers of the composite material to create a nanocomposite film being at least one of: a magnetic integrated circuit or a transmission line; and
the particles being magnetic.

26. The method of claim 21, further comprising:
attaching an electronic chip to a substrate sheet;
emitting layers of aerosol material onto a substrate to create different thicknesses of the aerosol material;
contacting a portion of the aerosol material against the electronic chip after the electronic chip is attached to the substrate sheet; and
adding at least one layer of a conductive material on top of the emitted composite material, the emitted aerosol material and the attached electronic chip to create a conductive trace.
